(19) United States
(12) Patent Application Publication
(10) Pub. No.: US 2010/0237875 A1
(43) Pub. Date: Sep. 23, 2010

(54) Unified brake and light tester

(76) Inventor: Dominador Limcolioc, Surrey (CA)

Correspondence Address: Antony C. Edwards, P.O. Box 26020, Westbank, BC, V4T 2G3, CA

(21) Appl. No.: 12/382,522

(22) Filed: Mar. 18, 2009

(51) Int. Cl. G01R 31/00

(52) U.S. Cl. 324/504

(57) ABSTRACT

A portable diagnostic device for checking electrical signalling systems of for example tractors and their trailers. The device has several receptacles for connection to a corresponding receptacle or pin connector of a trailer. One electrical circuit includes switches for energizing individual signalling or other circuits of the trailer individually, and indicating lamps and/or horns for annunciating circuit operability. Another electrical circuit includes switches for energizing individual signalling or illumination circuits individually, and indicating lamps and/or horns for annunciating circuit operability. The device, which is contained on a wheeled stand, has its own power supply and circuit overcurrent protective devices, and is thus independent.

### FIELD OF THE INVENTION

A portable diagnostic device for checking electrical signalling systems of for example tractors and their trailers. The device has several receptacles for connection to a corresponding receptacle or pin connector of a trailer. One electrical circuit includes switches for energizing individual signalling or other circuits of the trailer individually, and indicating lamps and/or horns for annunciating circuit operability. Another electrical circuit includes switches for energizing individual signalling or illumination circuits individually, and indicating lamps and/or horns for annunciating circuit operability. The device, which is contained on a wheeled stand, has its own power supply and circuit overcurrent protective devices, and is thus independent. The device enables a shop to perform safety checks.

### BACKGROUND OF THE INVENTION

As discussed in U.S. Pat. No. 6,043,661 which issued to Gutierrez on Mar. 28, 2000, vehicles such as buses are equipped with many signaling and safety features. Illuminated signaling lamps include: headlights, turn signal lights, four-way flashing lights, marker lights, tail lights, stop lights, beacon lights, reversing lights, and an eight-light warning system. Safety features may include redundant pneumatic braking systems and electrical braking systems which must be inspected periodically for operability of these signaling and safety systems.

Gutierrez discloses a wheeled apparatus which an individual technician can connect to a bus and/or a tractor trailer for the purpose of analyzing or monitoring the signaling systems. Most of these systems are electrical, and operate specified lamps. Other optional systems monitor pneumatic and hydraulic systems. The apparatus generates electrical signals for operating the various lamps on the school bus. Indicators provided on the apparatus indicate continuity of the various circuits, thus confirming operability of the bus lamps. The signal testing device is compatible with buses by installing modular wiring connectors for extending an electrical signaling system from the buses. A power supply is provided so that the device and the testing procedure are independent of the power supply of the bus. Overcurrent devices in the testing device provide protection to the circuitry. Flashers are provided to assist in identifying operation of lights which normally flash when operating, such as the turn signals and the four way alarm flasher. Additionally, the testing device has electrical power circuits for testing electric brakes, air pressure for testing the integrity of pneumatic braking systems, and hydraulic pressure for testing hydraulic servo lifting systems.

Applicant is also aware of U.S. Pat. No. 6,323,651 which describes an electrical and pneumatic device for a cargo trailer which device power sub-circuits that respectively power illumination and signaling lighting circuits and actuate the trailer pneumatic braking system. U.S. Pat. No. 6,154,035 for a Remote Control Fleet Safety Inspection System describes a safety inspection system that may be operably coupled to a trailer to enable a user to verify the operation of a plurality of lighting elements including clearance and running lights, hazard lights and brake lights and to allow further the verification of operation of an air brake system of the trailer. U.S. Pat. No. 5,602,482 for a Trailer Systems Tester provides a wheeled apparatus which may be connected to a freight trailer or other trailer for the purpose of analyzing the trailer signaling systems and pneumatic braking systems. Electrical signals are generated to operate the lamps on the trailer and indicators on the apparatus indicate the continuity of the various circuits to thereby confirm the operation of the trailer lamps. U.S. Pat. No. 5,488,859 for a Vehicle Testing Device and Method discloses a test device for testing the electrical and pneumatic safety systems of vehicles such as tractor trailers wherein electrical and pneumatic outputs of the vehicle are received for testing. U.S. Pat. No. 3,103,808 for a Portable Equipment Check Unit provides for testing the condition of lighting circuits and lights and for checking the condition and efficiency of the air brake system.

### SUMMARY OF THE INVENTION

In summary, the tester according to the present invention for performing safety checks on a vehicle or trailer having illumination and signal lighting circuits may be characterized as including one aspect electrical circuitry connectable to and for selectively energizing both audible and illumination annunciator signalling lighting circuits of corresponding annunciators; wherein the electrical circuitry has sub-circuits, each sub-circuit serving a selected illumination and signalling lighting circuit; and wherein each sub-circuit has a switch for selectively controlling it respective sub-circuit. The annunciators include both a lamp and an audible signalling device such as a horn responsive to successful energization of at least one of the sub-circuits.

A housing encloses the electrical circuitry. A plurality of dissimilar modular wiring connectors are provided, each having a plurality of conductors, where each individual conductor corresponds to one illumination and signalling function. Individual conductors for each like illumination and signalling function of modular wiring connectors are connected in parallel by the electrical circuitry to a predetermined sub-circuit. Like functions are thus energized and tested having different modular wiring connectors by a designated sub-circuit. At least one of the sub-circuits includes an elongate length of flexible pigtail connectors for electrical continuity testing remote from the housing and has an associated lamp and the audible signalling device cooperating therewith.

In one preferred embodiment the housing is mounted on a mobile stand supporting the housing. Wheels support the stand and handle is attached to a base of the stand for manoeuvring the stand. The stand is adapted for mounted of a battery on the base of the stand for stabilizing the stand the housing. The stand may advantageously include a substantially vertical riser section, such as a pole, extending upwardly from the base. The housing is mounted atop the riser section. The riser section or pole elevates the housing to substantially a waist height of a user.

### BRIEF DESCRIPTION OF THE DRAWINGS

In the figures wherein like characters of reference denote corresponding parts in each view:

FIG. 1 is an electrical schematic diagram of the trailer electrical testing circuits of the tester according to the present invention.

FIG. 2 is an electrical schematic diagram of the electrical continuity and light testing circuits of the tester according to the present invention.

FIG. 3 is an electrical schematic of the trailer air brake testing section of the tester according to the present invention.

FIG. 4 is in front perspective view, the face panel of the tester housing of the present invention containing the switches, corresponding annunciators, and the various gauges associated with the sub-circuits of the tester.

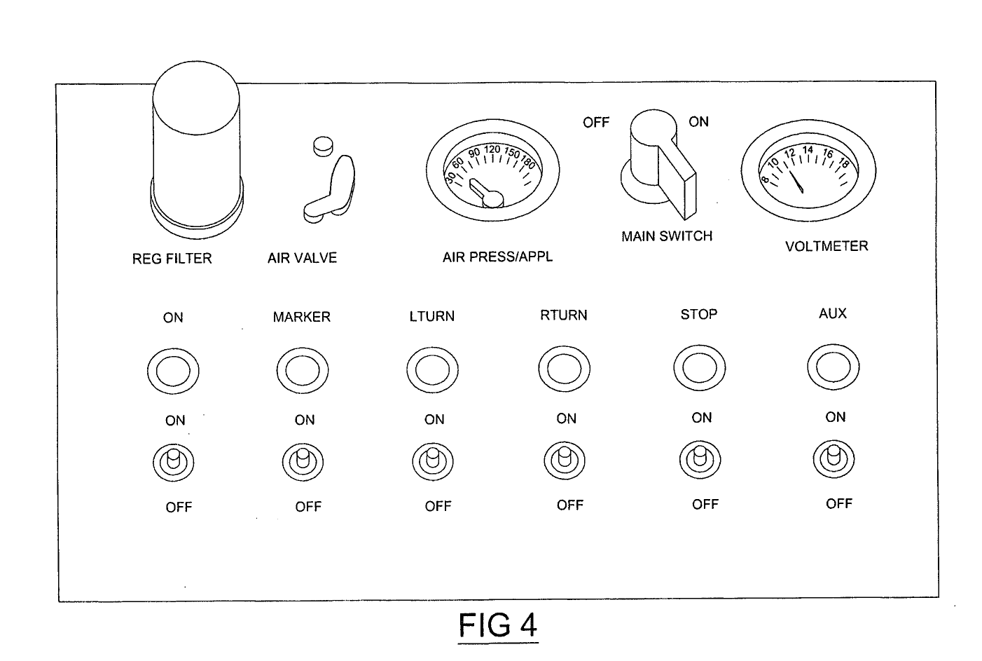

FIG. 5a is, in front perspective view, the tester housing mounted on its mobile stand.

FIG. 5b is, in rear perspective view, the tester and stand of FIG. 5a.

FIG. 5c is, in side perspective view, the tester and stand of FIG. 5a.

### DETAILED DESCRIPTION OF EMBODIMENTS OF THE INVENTION

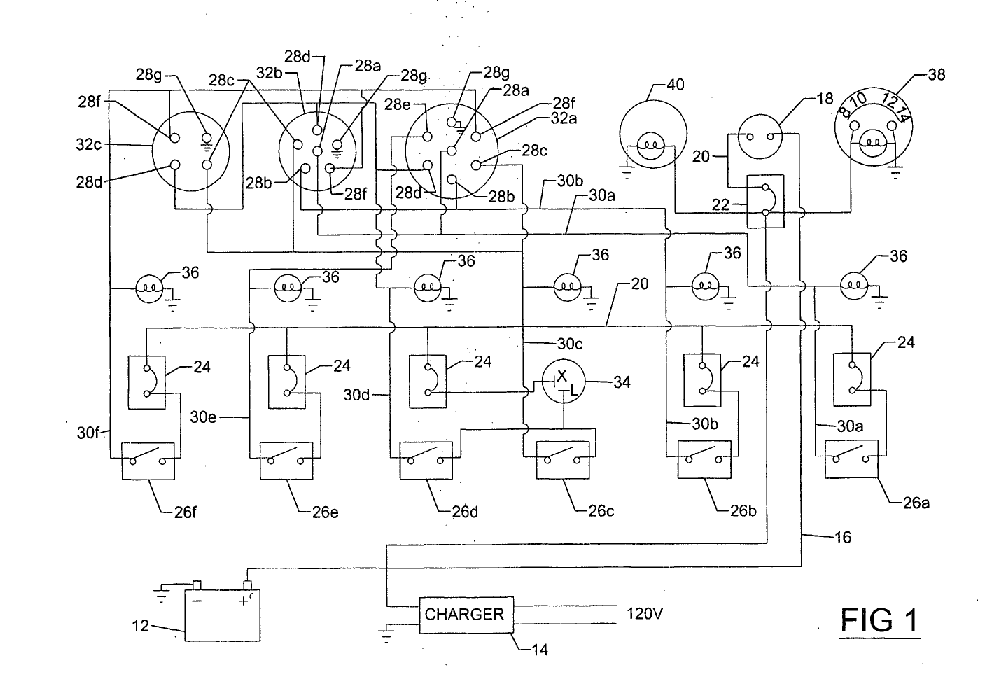

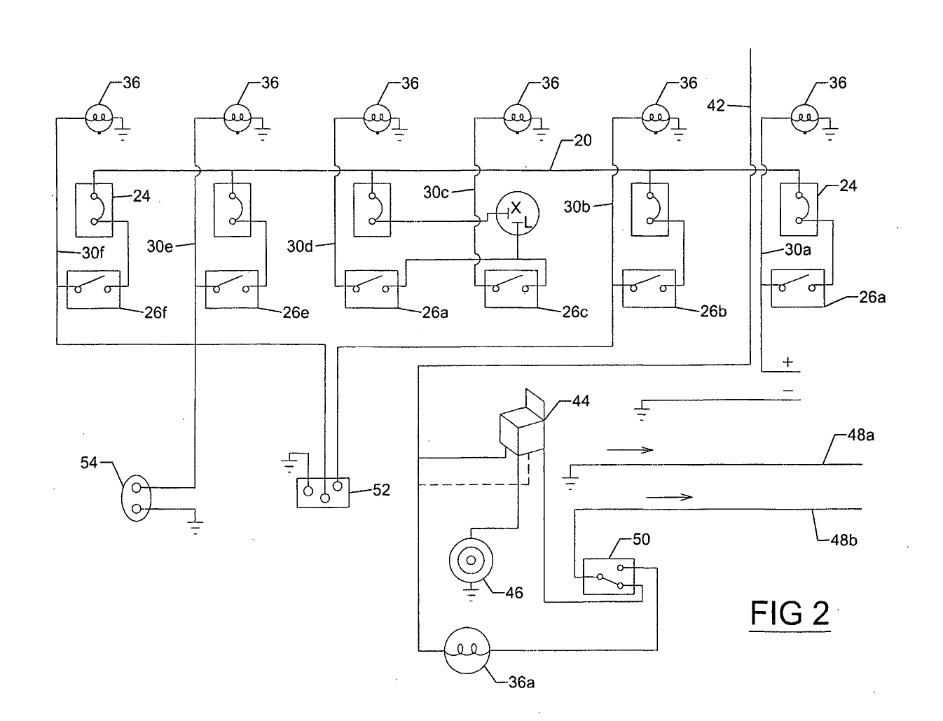

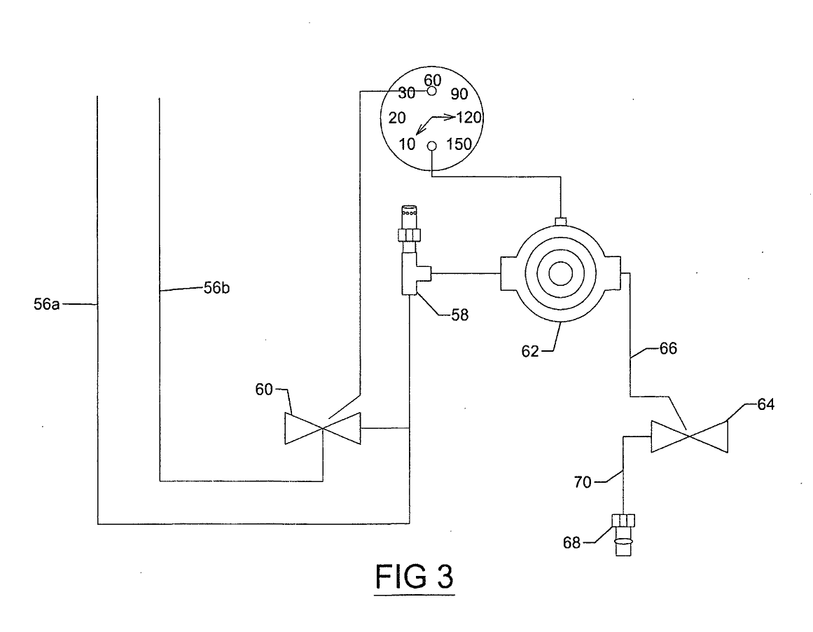

As set out in the schematic diagrams of FIGS. 1-3, the unified break and light electrical tester according to the present invention may be broken down into three schematic diagrams, namely, the trailer electrical tester schematic of FIG. 1, the electrical continuity and light tester schematic tester diagram of FIG. 2, and the trailer air-break tester section schematic diagram of FIG. 3.

As may be seen in FIG. 1, battery 12, charged by charger 14 connected to 120 volt mains, energizes circuit segment 16. Main switch 18 controls the energizing of circuit segment 20, which, via 30 amp circuit breaker 22 energizes the circuit segment 20 via 10 amp circuit breakers 24 up to switches 26a-26f. Switch 26a controls energizing of the auxiliary line and its corresponding pin receptacles 28a via circuit segment 30a. Pins 28a are, in this embodiment, and not intended to be limiting, the centre pin receptacles on the female plugs 32a and 32b used for testing the trailer lights.

Switch 26b controls the energizing of pin receptacles 28b via circuit segment 30b which in the illustrated embodiment is for testing the stop lights.

Switch 26c controls energizing of pin receptacles 28c via circuit segment 30c which in the illustrated embodiment is for testing the right turn signal lights. A flasher 34 is mounted in serial with the circuit breaker corresponding to the right turn switch 26c and the left turn switch 26d. Switches 26c and 26d are mounted in parallel from flasher 32. Switch 26d controls energizing of pins 28d via circuit segment 30d.

Switch 26e controls energizing of pin receptacles 28e via circuit segment 30e which energizes the marker plug receptacle 28e on female plug 32a. Switch 26f controls energizing pins 28f via circuit segment 30f which provides for testing of the tail lights. On all female plugs 32a-32c, pin receptacles 28g provide ground.

Individual pilot lamps 36 are provided on each of the circuit segments 30a-30f to indicate to the user when those circuits are energized.

In a preferred embodiment, a volt meter 38 and an air pressure gauge 40 are electrically connected to circuit segment 20 for example at circuit breaker 22.

FIG. 2 is a continuation of the schematic diagram of FIG. 1, and provides further features which are provided in a preferred embodiment of the present invention. Line 42 from the main circuit break 22 energizes pilot light 36a and, via relay 44 energizes both a horn 46 and a pair of continuity tester probes 48a and 48b via a two pole, single throw switch 50. When test probe 48b is electrically connected by switch 50, pilot 36a will light and horn 46 will sound when test probes 48a and 48b indicate an electrical continuity in the circuit being tested by the probes. Thus for example if a user is probing under a trailer or inside a vehicle engine compartment, or otherwise is testing part of an electrical system remote from the housing containing the tester electronics, and thus the user cannot easily see whether the pilot light 36a is lit, the audible signal provided by horn 46 indicates to the user that electrical continuity is present. This alleviates the user from either having a co-worker stand at the housing to monitor for the lighting of pilot light 36a, or from requiring a further pilot light be incorporated at the a remote location of the test probes where. The light may be easily be broken.

A pig-tail tester 52 is provided which is electrically connected to switches 26b and 26f to, respectively, test the stop and tail lights. Pigtail tester 52 preferably uses for example a 5 foot long pig-tail cord. A further pig-tail tester 54 is electrically connected to switch 26e for testing of sealed type trailer marker lights, again advantageously using for example a 5 foot long cord.

As seen in the schematic diagram of FIG. 3, the trailer air break tester section according to one aspect of the present invention includes pneumatic lines 56a and 56b wherein the air pressure in line 56a is directly connected to pressure release valve 58 and wherein line 56b is connected to pressure relief valve 58 via valve 60. Pressure release valve may for example be preset to relieve at 130 lbs pressure. Pressure relief valve 58 is connected to air pressure regulator and air water separator 62. Regulator/air-water separator 62 is connected to valve 64 via line 66. Valve 64 is connected to quick coupler 68 via line 70. Lines 56a and 56b are connected to the red and blue conventional so-called “glad hands” connectors respectively. Shop supplied pressurized air may be hooked up to quick coupler 68 to supply air to the “glad hands” connectors.

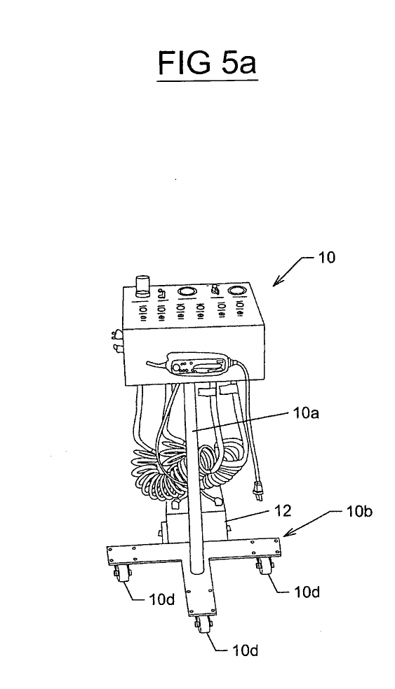

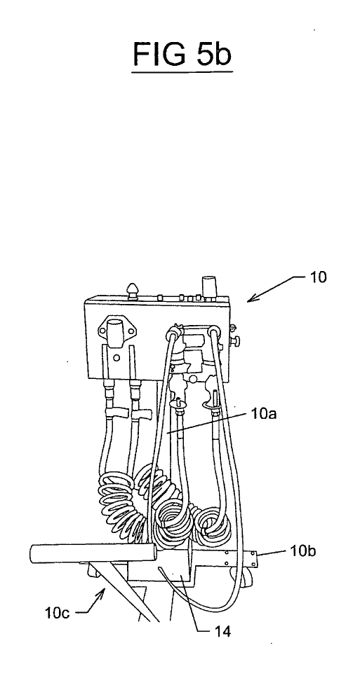

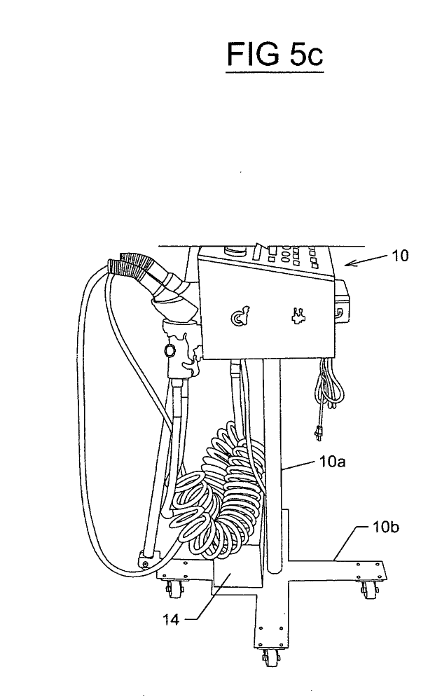

Thus, as will be appreciated by those skilled in the art, the above described unified brake and light tester according to the present invention is a combination of an airbrake tester, medium duty trailer electric brake tester and light tester mounted in a housing 10, itself mounted on a riser or pole 10a extending vertically from a wheeled base 10b as seen in FIG. 5a-5c. The housing 10 atop pole 10a is stabilized in part by the mounting of battery 12, for example a heavy lead-acid battery, down onto base 10b at the base of the pole. An elongate T-handle 10c mounted to base 10b allows the housing to be moved on its wheels 10d.

The tester may also be used to test electrical cords for continuity or short circuits or for testing power which comes from a tractor or trailer. The pilot light corresponding to the tests being performed will illuminate if power is detected as present in the circuit. In another embodiment, audible signals such as from a horn may sound if the pilot lights illuminate, a further pilot light and an audible indicator, again such as a horn, provides an indicator of continuity in the continuity testing circuit. In particular the audible indicator provides a useful remote indicator to a user who is performing continuity testing a remote distance away from the tester housing 10 containing the tester electronics which are the subject of FIGS. 1 and 2 so that if the user is checking for a continuity or short circuit the user is given feed-back as to whether or not the continuity or short circuit is detected.

The system's twelve volt battery 12 is backed up using a solid state charger 14. A 30 amp circuit breaker 22 on the main switch 18 provides primary electrical system protection and thereafter 10 amp circuit breakers 24 are provided on every subsequent switch to protect the tester and the wiring while the troubleshooting or repairing of the short circuit is being undertaken. Pig-tails 52 for testing marker lights and tail brake signals are provided. Advantageously pigtails 52 may be for example 5 feet long each for checking light bulbs without having to pull the light bulbs from their location on the vehicle or trailer. Power is also provided to the tester using alligator clips controlled by the individual switches 26a-26f. The alligator clips in the schematic of FIG. 2 are located where the power leads are labelled “+” and “−”.

The pneumatic circuit of the tester according to the present invention may be for example hooked to a pony or transfer trailer tarp and tailgate so as to check or test the operation of the tarp or tailgate actuator which are controlled by electrical (solenoid) over pneumatic valve and thus could be operated or tested with their respective switches provided in the tester according to the present invention.

Most shop air pressure are set up to 150 psi for power tools, and also lack the proper water drain in the air compressor or air system. Thus the tester of the present invention is equipped with a combination of an independent air pressure regulator and an air water separator. A preset relief valve protects the trailer air brake system, while the air water separator protects against water causing corrosion and freezing of the components in cold weather. The tester protects against water going into the system while a testing procedure is being performed.

As will be apparent to those skilled in the art in the light of the foregoing disclosure, many alterations and modifications are possible in the practice of this invention without departing from the spirit or scope thereof. Accordingly, the scope of the invention is to be construed in accordance with the substance defined by the following claims.

What is claimed is:

1. A tester for performing safety checks on a vehicle having illumination and signal lighting circuits, the tester comprising:
electrical circuitry connectable to and selectively energizing both audible and illumination annunciator signalling lighting circuits of corresponding annunciators;
said electrical circuitry having sub-circuits, each serving a selected illumination and signalling lighting circuit;
each said sub-circuit having a switch for selectively controlling its respective sub-circuit;
said annunciators including both a lamp and an audible signalling device responsive to successful energization of at least one of said sub-circuits;
a housing enclosing said electrical circuitry; and a plurality of dissimilar modular wiring connectors each having a plurality of conductors, each individual conductor corresponding to one illumination and signalling function, individual conductors for each like illumination and signalling function of each said modular wiring connector being connected in parallel by said electrical circuitry to a predetermined said sub-circuit, whereby like functions are energized and tested having different modular wiring connectors by a designated one of said sub-circuits,
said at least one of said sub-circuits includes an elongate length of flexible pigtail connectors for electrical continuity testing remote from said housing and has an associated said lamp and said audible signalling device cooperating therewith.

2. The tester according to claim 1, further to comprising a mobile stand supporting said housing;
wherein wheels support said stand; and a handle attached to a base of said stand, for manoeuvring said stand, and wherein said stand is adapted for mounted of a battery on said base of said stand for stabilizing said stand and said housing.

3. The tester according to claim 2, wherein said annunciators and audible signalling devices are comprised of lamps and horns respectively mounted on said housing.

4. The tester according to claim 3, wherein each said sub-circuit further comprises an. overcurrent protective device operably connected thereto.

5. The tester according to claim 1 wherein said pigtail connectors are at least substantially five feet long.

6. The tester of claim 2 wherein said stand includes a substantially vertical riser section extending upwardly from said base, and wherein said housing is mounted atop said riser section

7. The tester of claim 6 wherein said riser section elevates said housing to substantially a waist height of a user.

8. The tester of claim 7 wherein said riser section includes a pole.
